(19) United States
(12) Patent Application Publication
(10) Pub. No.: US 2009/0144887 A1
(43) Pub. Date: Jun. 11, 2009

(54) Solar powered motorcycle jacket

(76) Inventor: Koorosh Orandi, Bethesda, MD (US)

Correspondence Address: Koorosh Orandi, Apt. 310, 5401 Westbard Ave., Bethesda, MD, 20816, US

(21) Appl. No.: 12/001,188

(22) Filed: Dec. 11, 2007

(51) Int. Cl. A41D 13/00; A41D 3/02; H01L 31/042

(52) U.S. Cl. 2/455; 2/85; 2/93; 136/244

(57) ABSTRACT

The garment includes a plurality of surfaces that have one or more solar panels placed upon them. The garment utilizes an interface configured to transmit the collected solar energy to a storage system, which may be used to power an electrical device via a connector. This connector may power an electronic device, whereas another connector could jump start a battery. The garment could also use some of the stored energy to power one or more light-emitting diodes located on the exterior for any variety of illuminating purposes. The garment could also use some of the stored energy to power a heated article of clothing such as a removable lining, gloves, pants, and the like, or inversely, could instead power a removable cooling fan.

### TECHNICAL FIELD

The exemplary embodiments described herein relate to protective garments worn by motorcyclists for motorcycle riding and, more particularly, to protective garments worn by motorcyclists that include an energy collection mechanism (e.g., a solar energy collector). In certain non-limiting implementations, the energy collection mechanism may be connected to an external device (e.g., the motorcycle itself, a mobile phone, a flashlight, a radio, etc.) to provide it with power.

### BACKGROUND AND SUMMARY OF THE INVENTION

There are many dangers associated with motorcycle riding. Motorcyclists are much more likely to be injured in accidents than operators of larger motor vehicles, and as such, there are many existing protective garments being manufactured and produced worldwide specifically designed to reduce injury. Many injuries occur when motorcyclists fall off their bikes onto the ground at all rates of speed. Garments to protect riders in the event of a fall are typically constructed in a variety of styles, using a variety of materials for protection from head to toe. In terms of protective jackets and pants, some are comprised of mesh-type materials for increased ventilation, while others are comprised of a variety of textile and leather fabrics for increased abrasion and tearing resistance. Many jackets and pants also include protective armor panels (usually made from hard plastic, foam, or metal) for added impact protection in key areas. These panels can be placed on the inside or outside of a jacket, protecting areas such as the elbows, knees, and spine. Aside from the fabric variations, these panels are what primarily distinguish protective motorcycle garments from ordinary street clothing.

Many motorcycle jackets also contain a number of storage pockets and compartments for storing small devices, such as portable music players or cellular telephones. The vast majority of motorcycles have far less storage space than even the smallest of 4-wheeled vehicles, limiting the amount of tools and items a motorcyclist can carry on a trip. But much like automobile drivers, motorcycle riders frequently use both music players and cell phones on motorcycle rides. Cell phones are particularly important in the event of a mechanical breakdown or an accident. Unfortunately, due to the minimalist nature of motorcycles, most also use smaller batteries, and the vast majority do not have 12-volt power accessory sockets as cars do. In the event of a mechanical breakdown, a motorcyclist might be in a dire situation if simultaneously faced with a dying cell phone battery and the prospect of having to charge it. Even if the motorcyclist were to have a cell phone charger and a 12-volt socket to plug it into, a standard motorcycle battery would not be strong enough to charge or maintain phone power for very long.

Thus, it will be appreciated that there is a need in the art of motorcycling to overcome the problem of lacking a portable power source for electronic accessories. A renewable power source, such as solar energy, would be advantageous for powering devices while away from a permanent power source. There are existing designs for solar panel systems that can be attached to the windshield of a motorcycle, providing a non-mobile power source for motorcycle ignition. There are also existing designs for ordinary street clothing, especially jackets, which have solar panels to power electronic devices as well. Certain example embodiments here may comprise a protective, e.g., armored motorcycle jacket, but adding solar paneling and electrical outlets to power various devices. Certain example embodiments also may incorporate a battery charger to store power in the event of a loss of sunlight, to extend the usefulness of the system. The batteries may be in certain non-limiting implementations standard NiMH, NiCd, or other rechargeable batteries, and may store enough power for several hours. Overall, this type of system would greatly expand the garment's versatile uses and value when on motorcycle trips.

### BRIEF DESCRIPTION OF THE DRAWINGS

FIG. 1 represents a front view of the jacket.

FIG. 2 represents a back view of the jacket.

FIG. 3 represents an illustration of a typical solar-powered outdoors jacket.

FIG. 4 represents an illustration of a typical non-motorcycle jacket that utilizes LED-lights for increased visibility.

### DETAILED DESCRIPTION OF ILLUSTRATED EMBODIMENTS

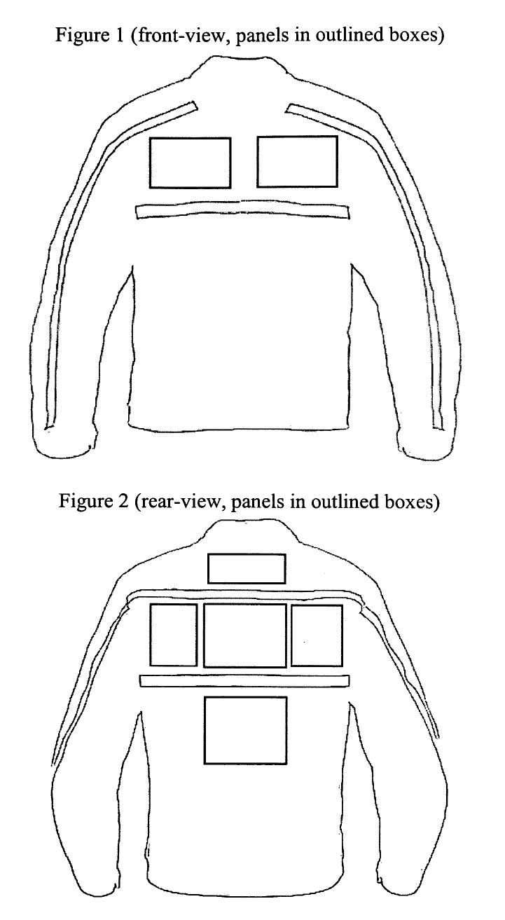

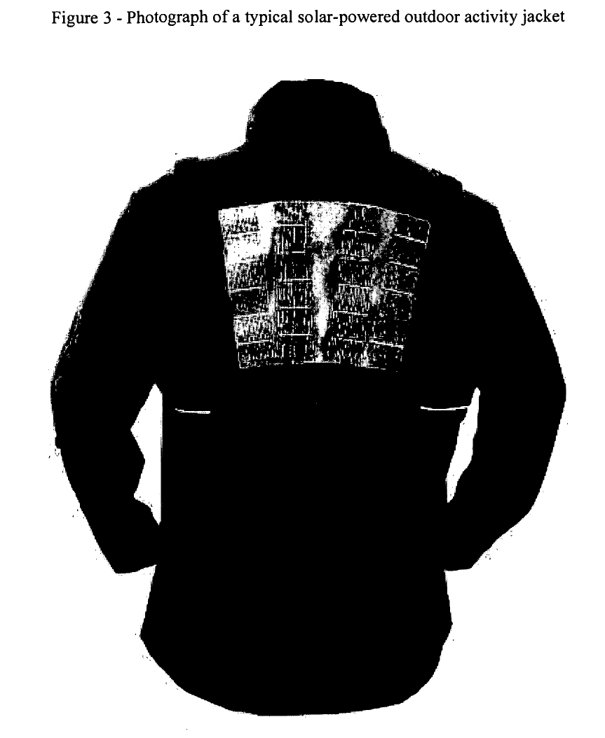

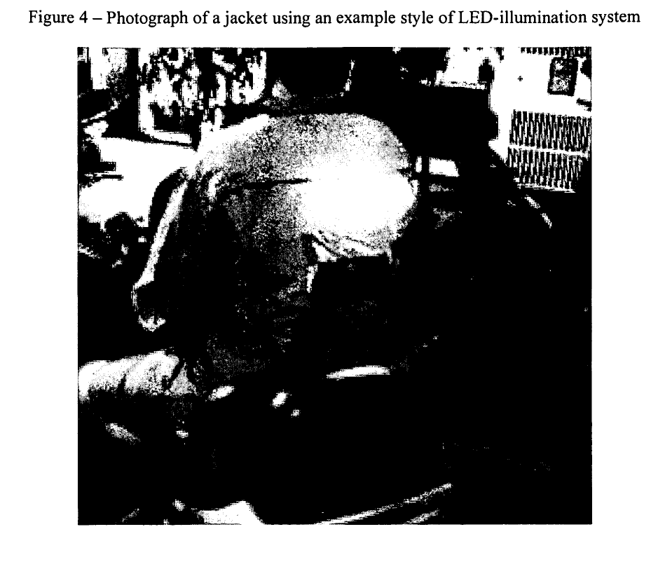

The garment appears mostly like an ordinary armored motorcycle jacket. In FIG. 1, a frontal view of the jacket is presented, with potential solar panel locations on both sides of the chest 1. In FIG. 2, a rear view of the jacket is presented, with more solar panel locations all over the back area 2. Due to the need for greater flexibility on the rear part of the jacket, there optionally are multiple small flexible solar panels extending up and down the spinal area, as well as one small panel over each shoulder blade. The panels may still occupy a good amount of surface area, but may in addition, or in the alternative, be spread into pieces to allow greater freedom of movement. These panels can also be easily replaceable in the event of damage. Underneath the outer layer of the jacket, armor panels can also be placed to protect against injury in any number of locations. FIG. 3 represents an example illustration of an existing solar powered jacket, to depict a typical example of how solar panels can be arranged on the rear of a jacket. FIG. 4 represents an example illustration of an existing non-motorcycling jacket, but worn by a motorcyclist, and utilizing a set of LED-lights to increase rearward visibility by other vehicles.

The interior of the jacket may house the necessary wiring and capacitors to store the energy gathered from the panels, which may extend the usefulness of the jacket beyond daylight hours. The wiring and battery components can be located anywhere throughout the interior of the jacket. The solar panels will ultimately feed power to a direct current electrical outlet, with a type of connector attached. An example embodiment could utilize a universal serial bus connector, to allow for some flexibility in connecting a charging cable for a portable music player, a cellular phone, a navigation system, a radar detector, or any other device that could be powered by such a cable. Another example embodiment could utilize clamp-type connectors to jump start a battery. In a different example embodiment, a different connector could power a type of portable lighting device. In another example embodiment, a built-in lighting system on the exterior of the jacket could increase the rider's visibility during ordinary evening or night riding. This example embodiment could include light-emitting diodes arranged in a way that would illuminate the rider's sides or back to increase his or her visibility to other vehicle drivers, which is a very important factor in avoiding collisions. Another example embodiment could have lights arranged in a frontal pattern to illuminate a path in front of the rider.

Another potential embodiment could involve the use of a heating system for the rider as well. For motorcycles that use smaller windshields (or even none at all), forward velocities of as little as 30-40 miles per hour can greatly reduce a rider's body temperature. In colder temperatures, the first parts of a rider to get cold are typically the hands, feet, and neck. The feel of cold hands or feet can lead to slower physical reaction times, and an inability to properly control a motorcycle. As such, there are existing heated motorcycle jackets and heated motorcycle gloves for this very reason. But as of now, the typical way to power these devices is by connecting them to a motorcycle's battery. This requires a bit of wiring, and again, in the event of a breakdown or battery failure, this method could potentially become useless. So, a potential embodiment for the present invention could include a heated lining system that can be easily removable, but powered by the jacket. The garment could connect to the liner, or the garment could connect to gloves, or both if necessary. The added benefit of this type of heating system is that it is not reliant on the power provided by the motorcycle, but another potential embodiment could involve drawing power from the jacket, the motorcycle, or both combined. Additionally, the garment could potentially be configured to power a small cooling fan, as in warmer temperatures, motorcycle jackets have the ability to greatly increase a rider's body temperatures as well.

Connector cables may be included in, e.g., removably connected or retractably attached to, the jacket. The panels and/or storage mechanisms may be encased in a protective, at least partially water impermeable, material such as, for example, nylon. Optionally, the jacket may contain a heating element, drawing power from one or both of the motorcycle and the power storage mechanism of the jacket. A second connector may be provided so that the power storage medium may be connected to an AC power source (e.g., a wall socket) to pre-charge or re-charge the jacket before use. The power storage medium may include fiber-like battery storage devices, which may be woven into the jacket.

Although certain exemplary embodiments have been described as relating to a jacket, it will be appreciated that the techniques of certain exemplary embodiments may be used in connection with any suitable garment, such as, for example, a jacket, pants, a shirt, gloves, shorts, a helmet, and/or the like.

While the present invention has been described in connection with certain embodiments, it is understood that the same is provided by way of example and without limitation, the scope of the invention being limited solely by the claims. Additionally, it is understood that various modifications, styles, and changes may be made without departing from the scope and the spirit of the invention.

What is claimed is:

1. A protective clothing garment comprising:
a plurality of solar panels disposed on one or more outer surfaces of the garment;
a power storage medium configured to at least temporarily store collected energy from the plurality of solar panels in rechargeable batteries when sunlight is absorbed by the panels; and
an interface configured to provide energy from the power storage medium to a connected electronic device via a connector connecting the interface and the electronic device, the electronic device being external to the garment.

2. The garment of claim 1, further comprising a second connector for connecting an alternative-current power source to the power storage medium to charge the storage medium.

3. The garment of claim 1, further comprising light-emitting diodes located on one or more of the outer surfaces of the garment.

4. The garment of claim 1, wherein the power storage medium is at least one rechargeable battery.

5. The garment of claim 1, wherein the garment is a jacket.

6. The garment of claim 1, wherein the connector is a universal serial bus connector.

7. The garment of claim 1, further comprising a retractable connector for connecting the interface to an electronic device.

8. The garment of claim 1, wherein the garment is comprised of one or more heated articles of clothing.

9. The garment of claim 1, wherein the garment is comprised of a removable cooling fan.
